(19) United States
(12) Patent Application Publication
(10) Pub. No.: US 2025/0276891 A1
(43) Pub. Date: Sep. 4, 2025

(54) ENCAPSULATED MEMS DEVICES

(71) Applicant: TEXAS INSTRUMENTS INCORPORATED, Dallas, TX (US)

(72) Inventors: Jane Qian LIU, Plano, TX (US); Paul Erhard KONRAD, Allen, TX (US); Ying-Chang CHEN, Hsinchu Hsien (TW)

(21) Appl. No.: 18/592,056

(22) Filed: Feb. 29, 2024

(51) Int. Cl. B81B 7/00; B81C 1/00

(52) U.S. Cl. CPC B81B 7/0038; B81C 1/00285; B81B 2207/097; B81C 2203/0163; B81C 2203/019

(57) ABSTRACT

In examples, a micro-electromechanical (MEMS) device comprises a substrate and a semiconductor die coupled to the substrate and including circuitry formed therein. The semiconductor die also includes a bond pad coupled to the circuitry. The MEMS device includes a structure extending away from the semiconductor die and having four sides, with the structure comprising a corrodible material. The MEMS device includes an epoxy contacting outer surfaces of the four sides of the structure and over the corrodible material.

### BACKGROUND

Micro-electromechanical systems (MEMS) devices integrate miniature mechanical elements, sensors, actuators, and electronics onto a single silicon substrate. These compact systems, typically ranging from micrometers to millimeters in size, use microfabrication principles to create functional devices. MEMS technology has diverse applications across industries such as aerospace, healthcare, telecommunications, and consumer electronics. The miniaturization and integration capabilities of MEMS devices enable the development of efficient and cost-effective solutions, offering improved performance and functionality compared to traditional, macro-scale counterparts.

### SUMMARY

In examples, a micro-electromechanical (MEMS) device includes a substrate and a semiconductor die coupled to the substrate and including circuitry formed therein. The semiconductor die also includes a bond pad coupled to the circuitry. The MEMS device includes a structure extending away from the semiconductor die and having four sides, with the structure including a corrodible material. The MEMS device includes an epoxy contacting outer surfaces of the four sides of the structure and over the corrodible material.

In examples, a method of manufacturing a micro-electromechanical (MEMS) device includes attaching a first semiconductor die to a substrate panel and attaching a first structure to the substrate panel around the first semiconductor die, with the first structure including a first metal stack. The method includes attaching a second semiconductor die to the substrate panel and attaching a second structure to the substrate panel around the second semiconductor die, with the second structure including a second metal stack. The method includes depositing an epoxy contacting first and second surfaces of the first structure and contacting third and fourth surfaces of the second structure and in a gap between the second surface of the first structure and the third surface of the second structure. The method includes singulating the substrate panel including cutting through epoxy in the gap and through a portion of the substrate panel.

### BRIEF DESCRIPTION OF THE DRAWINGS

FIG. 1A is a block diagram of an automotive system including an encapsulated MEMS device, in accordance with various examples.

FIG. 1B is a block diagram of a system including an encapsulated MEMS device, in accordance with various examples.

FIGS. 2A and 2B are different cross-sectional views of an encapsulated MEMS device, in accordance with various examples.

FIG. 2C is a top-down view of an encapsulated MEMS device, in accordance with various examples.

FIG. 2D is a perspective view of an encapsulated MEMS device, in accordance with various examples.

FIG. 2E is a cross-sectional view of an encapsulated MEMS device, in accordance with various examples.

FIG. 2F is a top-down view of an encapsulated MEMS device, in accordance with various examples.

FIG. 2G is a perspective view of an encapsulated MEMS device, in accordance with various examples.

FIGS. 3A and 3B are different cross-sectional views of an encapsulated MEMS device, in accordance with various examples.

FIG. 3C is a top-down view of an encapsulated MEMS device, in accordance with various examples.

FIG. 3D is a perspective view of an encapsulated MEMS device, in accordance with various examples.

FIG. 3E is a cross-sectional view of an encapsulated MEMS device, in accordance with various examples.

FIG. 3F is a top-down view of an encapsulated MEMS device, in accordance with various examples.

FIG. 3G is a perspective view of an encapsulated MEMS device, in accordance with various examples.

FIG. 4 is a flow diagram of a method for manufacturing an encapsulated MEMS device, in accordance with various examples.

FIGS. 5A1-5E3 are a process flow for manufacturing an encapsulated MEMS device, in accordance with various examples.

FIG. 6 is a flow diagram of a method for manufacturing an encapsulated MEMS device, in accordance with various examples.

FIGS. 7A1-7E3 are a process flow for manufacturing an encapsulated MEMS device, in accordance with various examples.

### DETAILED DESCRIPTION

MEMS devices have varying structures and operations. For example, some MEMS devices include a substrate, a semiconductor die containing circuitry, an array of mirrors at a device side of the die, and a glass panel above the array of mirrors. Such MEMS devices are particularly useful in optical applications. For instance, the mirrors may be configured to reflect incoming light in particular directions to achieve application-specific objectives. Other MEMS devices may be structured differently, containing accelerometers, gyroscopes, sensors, and other such micro-scale components that are useful in a variety of other applications. Many types of MEMS devices include orifices through which deleterious environmental influences, such as moisture and debris, can enter and damage vulnerable components, such as metal stacks, glass panels, and mirror arrays.

This disclosure describes various examples of a MEMS device that mitigates the risk of damage by environmental factors such as moisture and debris, as described above. In examples, a MEMS device includes a substrate having a metal trace exposed to an outer surface of the substrate. The MEMS device includes a semiconductor die coupled to the substrate and a bond pad coupled to the metal trace by way of a bond wire. The semiconductor die has a device side including a mirror. The MEMS device further includes a four-sided structure including a metal stack. The structure is coupled to the device side of the semiconductor die and to a glass member. The structure forms a sealed cavity between the semiconductor die and the glass member. The MEMS device includes an epoxy contacting each of the four surfaces of the structure. The epoxy seals orifices between the semiconductor die and the glass member, protecting vulnerable components of the MEMS device, such as the aforementioned structure (which may be composed of, e.g., one or more corrodible metals). Consequently, the example MEMS devices described herein experience substantially increased longevity, with the example MEMS devices gaining at least an additional 10,864 hours of operational life over existing MEMS devices in experimental salt challenge testing.

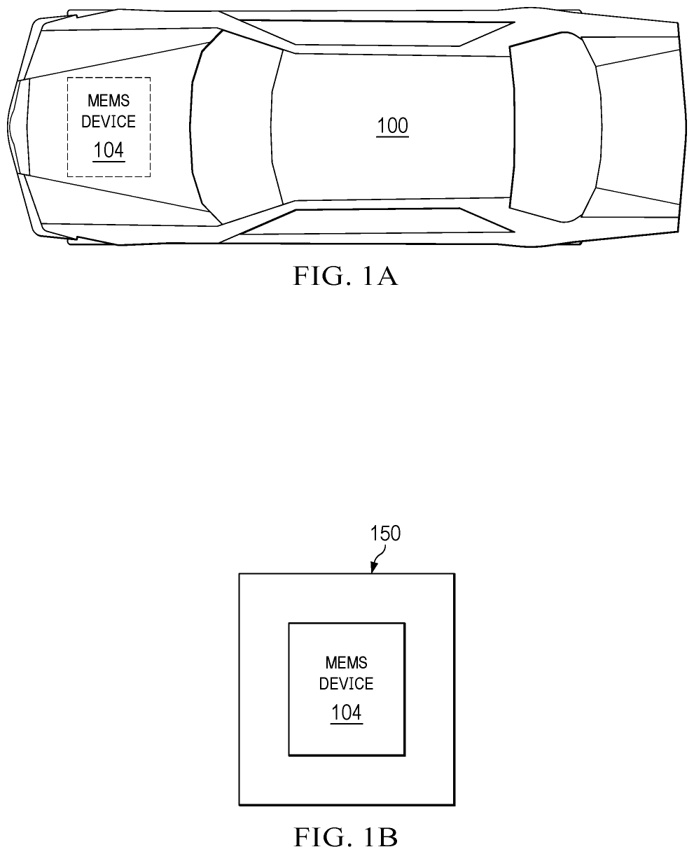

FIG. 1A is a block diagram of an automotive system 100 including an encapsulated MEMS device, in accordance with various examples. The automotive system 100 may be a car, pickup truck, cargo truck, etc. The automotive system 100 may include a MEMS device 104, which may take the form of any of the various example MEMS devices described herein. Within the automotive system 100, the MEMS device 104 may be deployed in a variety of applications, including displays, projection systems, airbag systems, tire pressure monitoring systems, fuel injection systems, navigation systems, electronic stability control systems, engine control systems, etc.

FIG. 1B is a block diagram of a system 150 including an encapsulated MEMS device, in accordance with various examples. The system 150 may be any type of electronic device, such as automobiles, electronic appliances (e.g., refrigerators, microwave ovens, clothing washers and dryers), media devices (e.g., projectors, televisions, audio equipment), cameras, smartphones, personal computers, notebooks, tablets, aircraft, spacecraft, etc. The system 150 also may find application in marine environments, and in at least some examples, may take the form of watercraft. The system 150 may include a MEMS device 104, which may take the form of any of the various example MEMS devices described herein.

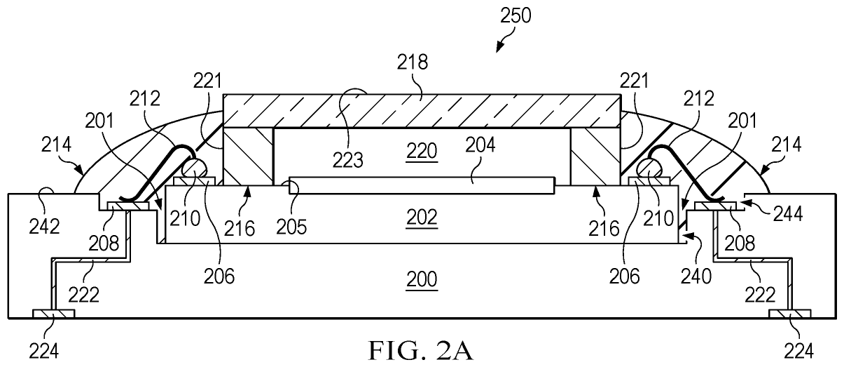

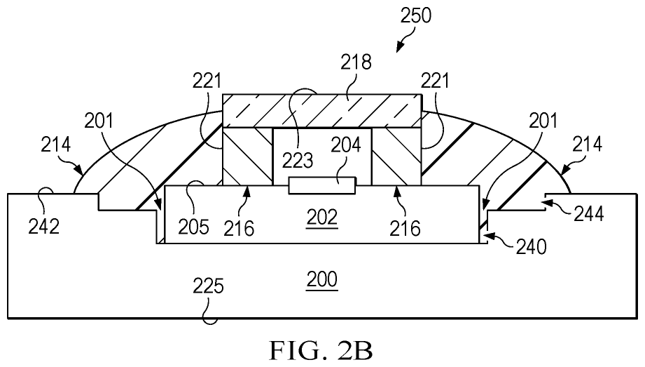

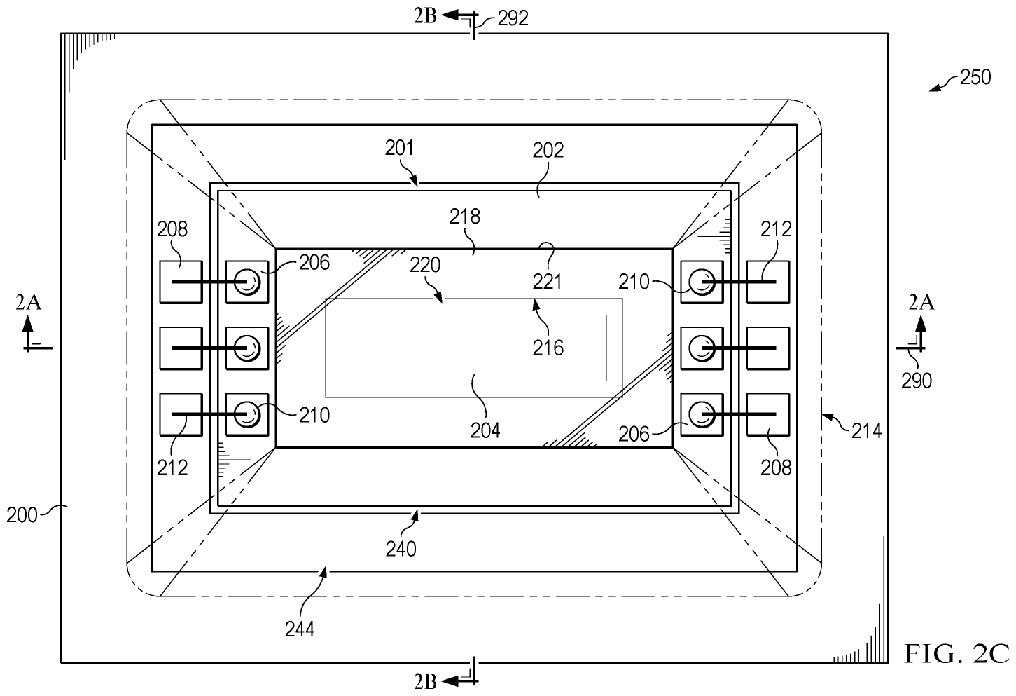

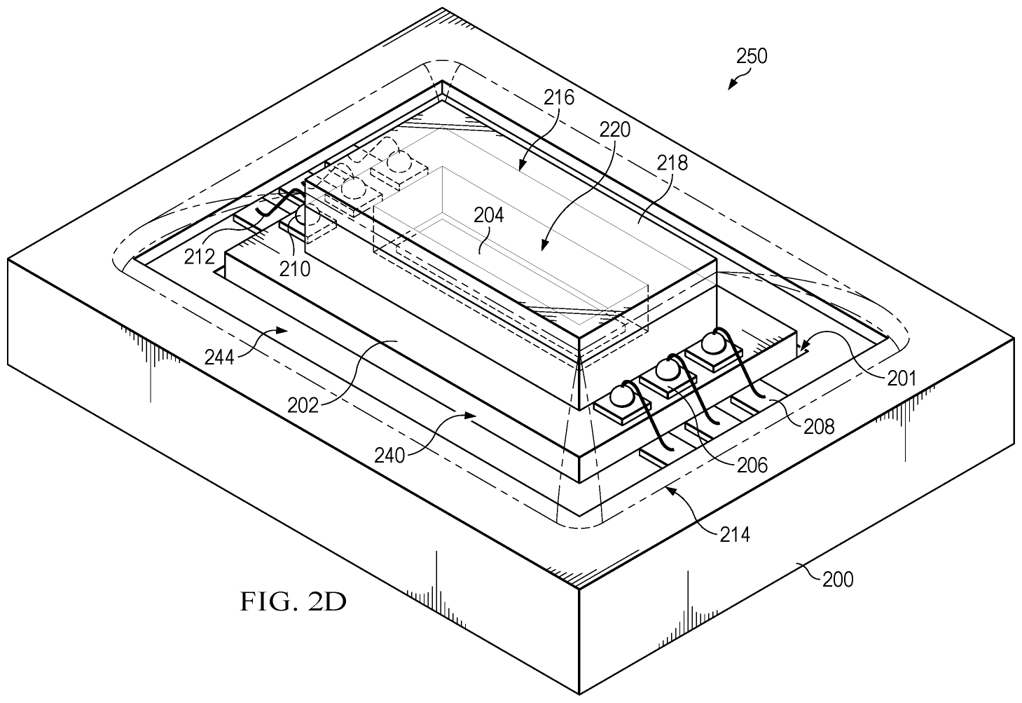

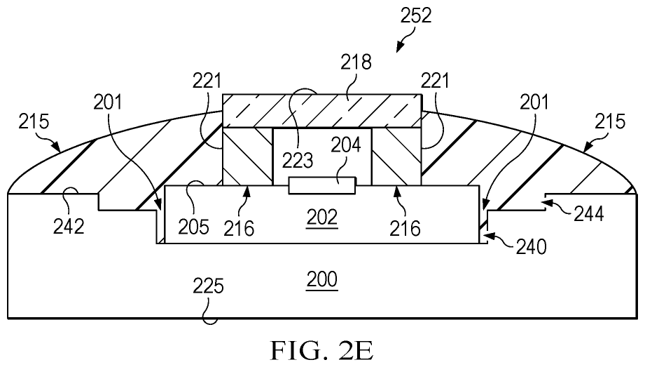

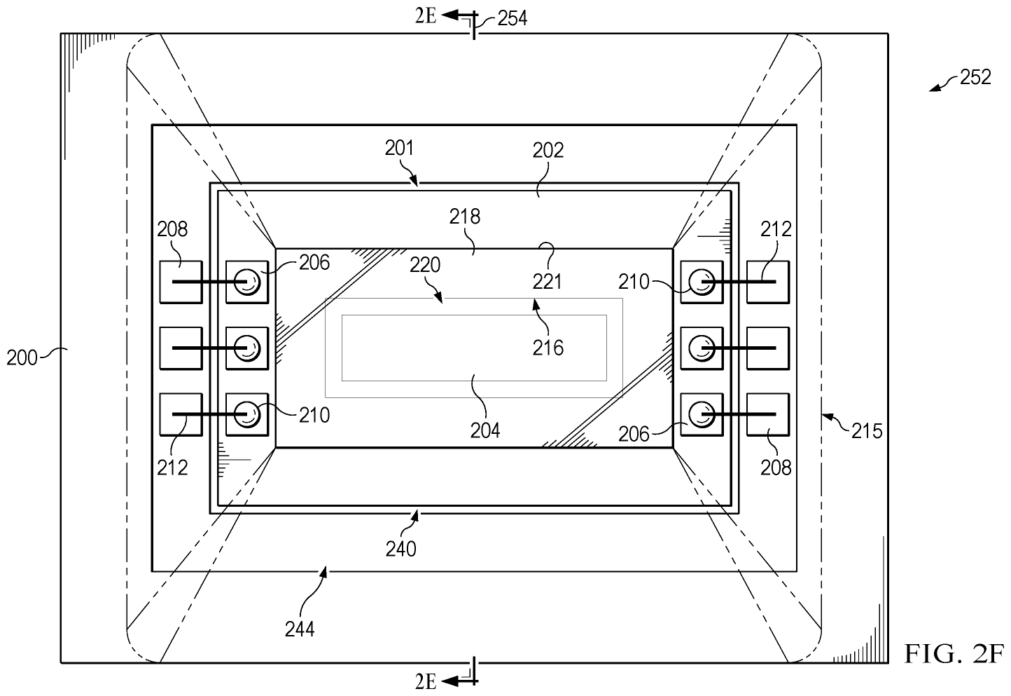

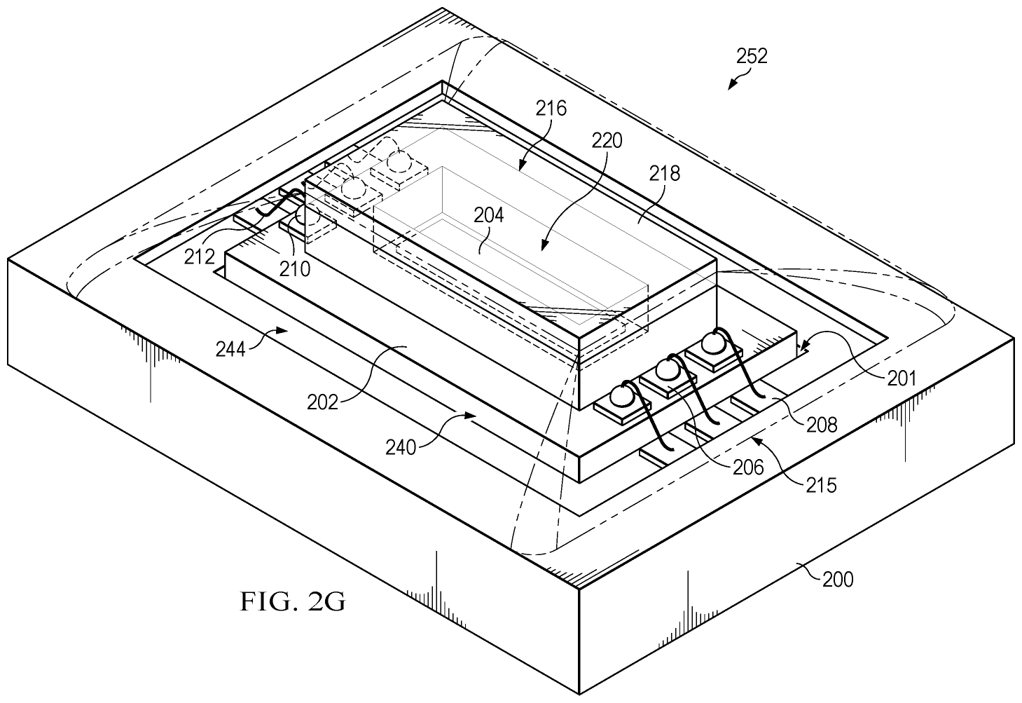

FIGS. 2A and 2B are different cross-sectional views of an encapsulated MEMS device, in accordance with various examples. FIG. 2C is a top-down view (i.e., a view toward the active circuitry of the MEMS device, as opposed to a non-device side of the MEMS device) of the MEMS device of FIGS. 2A and 2B, in accordance with various examples. FIG. 2D is a perspective view of the MEMS device illustrated in FIGS. 2A-2C, in accordance with various examples. The cross-section of FIG. 2A is taken along line 290 shown in FIG. 2C, and the cross-section of FIG. 2B is taken along line 292 shown in FIG. 2C.

More particularly, FIGS. 2A-2D show a MEMS device 250, which is an example of the MEMS device 104 described above. The MEMS device 250 includes a substrate 200, which in some examples may be a ceramic substrate. The MEMS device 250 includes a semiconductor die 202 on the substrate 200. The semiconductor die 202 may include one or more devices 204 on a device side 205 of the semiconductor die 202. The one or more devices 204 may include circuitry (e.g., complementary metal oxide semiconductor (CMOS) circuitry), one or more mirrors, other MEMS mechanical devices, etc. that may be susceptible to damage by moisture, salt, debris, and other external contaminants. The MEMS device 250 includes bond pads 206 and bond leads 208 on the substrate 200. A ball bond 210 is coupled to the bond pad 206, and a bond wire 212 is coupled to the ball bond 210 and to the bond lead 208 (e.g., such as by a stitch bond). Other types of bonds besides ball bonds and stitch bonds are contemplated and included in the scope of this disclosure.

In examples, the MEMS device 250 includes a cavity 240 in which the semiconductor die 202 is positioned. However, in other examples, the cavity 240 may be omitted, and the semiconductor die 202 may be placed on a flat surface that is horizontally coplanar with other surfaces within the MEMS device 250, such as a surface 242 or a shelf 244. In examples, the bond leads 208 are positioned on the shelf 244, which circumscribes the semiconductor die 202. However, in examples, the shelf 244 may be omitted, and the bond leads 208 may be positioned elsewhere, such as on the surface 242.

An epoxy 214 covers various components of the MEMS device 250, such as the bond pads 206, bond leads 208, the ball bond 210, the bond wire 212, and portions of the substrate 200. The epoxy 214 contacts and partially covers, but does not completely surround, the substrate 200. The epoxy 214 also contacts and covers a multi-sided (e.g., four-sided) structure 216 that extends approximately orthogonally from the device side 205 in the vertical direction and extends approximately parallel to each side of a perimeter of the semiconductor die 202 in the horizontal direction. In examples, the epoxy 214 contacts and covers the outer surfaces of the multi-sided structure 216. The epoxy 214 contacts and partially covers a cap 218 (e.g., a glass panel; a filter for gas or liquid sensing applications; fluidic channels in microfluidic applications) that is coupled to the structure 216. The cap 218 is approximately parallel to the semiconductor die 202. The structure 216 may be composed of a corrodible material. The structure 216 may include, for instance, a metal stack and an optional interposer (e.g., a semiconductor interposer) that, together with the cap 218, form a seal (e.g., a hermetic seal) enclosing a cavity 220. The epoxy 214 contacts and covers an outer surface 221 of the structure 216 that faces away from the cavity 220. The epoxy 214 contacts and covers part of the cap 218, but in examples, the epoxy 214 does not contact or cover any portion of a top surface 223 of the cap 218. A gap 201 between the substrate 200 and the semiconductor die 202 is sufficiently large that the semiconductor die 202 may be placed in the substrate 200 without colliding with one or more walls of the substrate 200. The epoxy 214 seals the various components that the epoxy 214 contacts and covers and is fluid-resistant, protecting such components from moisture, debris, and other damaging environmental influences.

The epoxy 214 may be a glob top epoxy, a mold compound, or any other suitable epoxy or non-epoxy material that serves the purposes and performs the functions attributed herein to the epoxy 214. The epoxy 214 is composed of at least 80% silica, because a composition lower than 80% silica presents technical disadvantages such as the application of mechanical and/or thermal stress to the MEMS device 250 that can damage various components of the MEMS device 250 (e.g., cracking of the cap 218, breaking and/or lifting of bond wires 212, cracking of the substrate 200). The epoxy 214 has a coefficient of thermal expansion below 25, because a coefficient of thermal expansion at or above 25 presents technical disadvantages, such as the application of mechanical and/or thermal stress to the MEMS device 250 that can damage various components of the MEMS device 250 (e.g., cracking of the cap 218, breaking and/or lifting of bond wires 212, cracking of the substrate 200). The epoxy 214 has a thickness adequate to cover all metals, alloys, and oxide layers in the structure 216, as well as the bond wires 212. Covering the structure 216 includes covering most or all of the surface 221 (e.g., including any orifices, interfaces between layers, and metal surfaces), as well as the interface between the structure 216 and the cap 218. A thickness of the epoxy 214 that fails to cover most or all (e.g., including any orifices, interfaces between layers, and metal surfaces) of the surface 221 as well as the interface between the structure 216 and the cap 218 is technically disadvantageous because the structure 216, and particularly the metals in the structure 216, is vulnerable to corrosion and/or oxidation, and because the MEMS device 250 becomes vulnerable to infiltration and damage by external contaminants, such as salt, moisture, etc. However, if the epoxy 214 is so thick that the epoxy 214 covers substantially more than the surface 221 and the interface between the structure 216 and the cap 218, this thickness becomes technically disadvantageous by adding expense and bulk without commensurate benefit, and by possibly covering some or all of the top surface of the cap 218 in optical applications (e.g., if the cap 218 is a glass panel). Further, an excess of epoxy 214 in the lateral direction (i.e., covering more of the substrate 200 than necessary) can cause challenges in deploying the MEMS device 250 in certain systems, such as those systems that use parts of the substrate 200 as optical reference points to ensure that the MEMS device 250 is properly seated and aligned within the system.

The substrate 200 includes a metal trace 222 that is coupled to the bond lead 208 and to a metal contact 224 on an exterior and/or bottom surface 225 of the substrate 200. The metal trace 222, the bond lead 208, the bond wire 212, the ball bond 210, and the bond pad 206 establish an electrical pathway between the metal contact 224 and circuitry of the semiconductor die 202.

The view of FIG. 2B is similar to the view of FIG. 2A, except that in the cross-section of FIG. 2B, bond pads and bond wires are not present. Despite the absence of bond pads and bond wires in the cross-section of FIG. 2B, the epoxy 214 is still present, contacting and covering some or all of the substrate 200, the semiconductor die 202, the structure 216, and the cap 218.

As shown and as described above, the structure 216 is four-sided, with each of the four sides extending approximately parallel to a different side of the semiconductor die 202. The four sides of the structure 216 thus intersect approximately at right angles with each other. The epoxy 214 contacts and covers the outer surfaces 221 of the four sides of the structure 216.

The manner in which a MEMS device is manufactured (example manufacturing techniques are described in detail below) can affect the configuration of the epoxy 214. In the example MEMS device 250 illustrated in FIGS. 2A-2D, the epoxy 214 extends in the horizontal direction from the structure 216 and cap 218 to the substrate 200, but the epoxy 214 does not extend to the outer perimeter of the substrate 200. In contrast, as shown in the cross-sectional, top-down, and perspective views of FIGS. 2E-2G, respectively, an example MEMS device 252 (which is an example of MEMS device 104) may include an epoxy 215 extends in the horizontal direction from the structure 216 and the cap 218 to the outer perimeter of the substrate 200 (e.g., to two sides of the outer perimeter of the substrate 200, or to four sides of the outer perimeter of the substrate 200). Line 254 in FIG. 2F indicates the cross-section of FIG. 2E. The greater area occupied by the epoxy 215 in the example MEMS device 252 of FIG. 2E and the lesser area occupied by the epoxy 214 in the example MEMS device 250 of FIGS. 2A-2D is a function of the specific manufacturing technique used to form the MEMS device, and, as mentioned, the different manufacturing techniques resulting in these differing epoxy configurations are described in detail below.

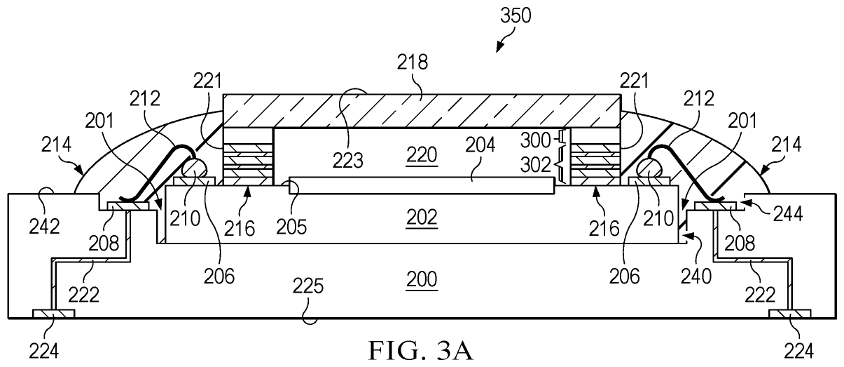

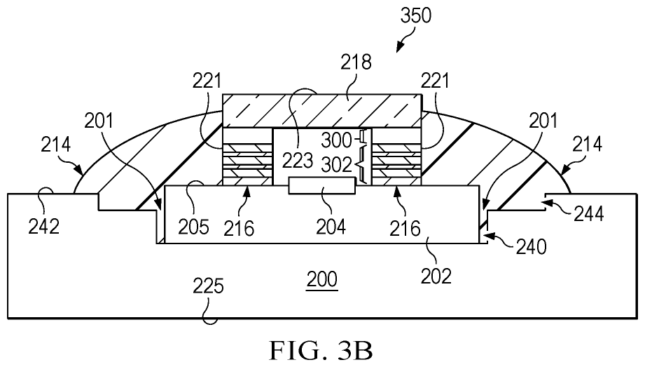

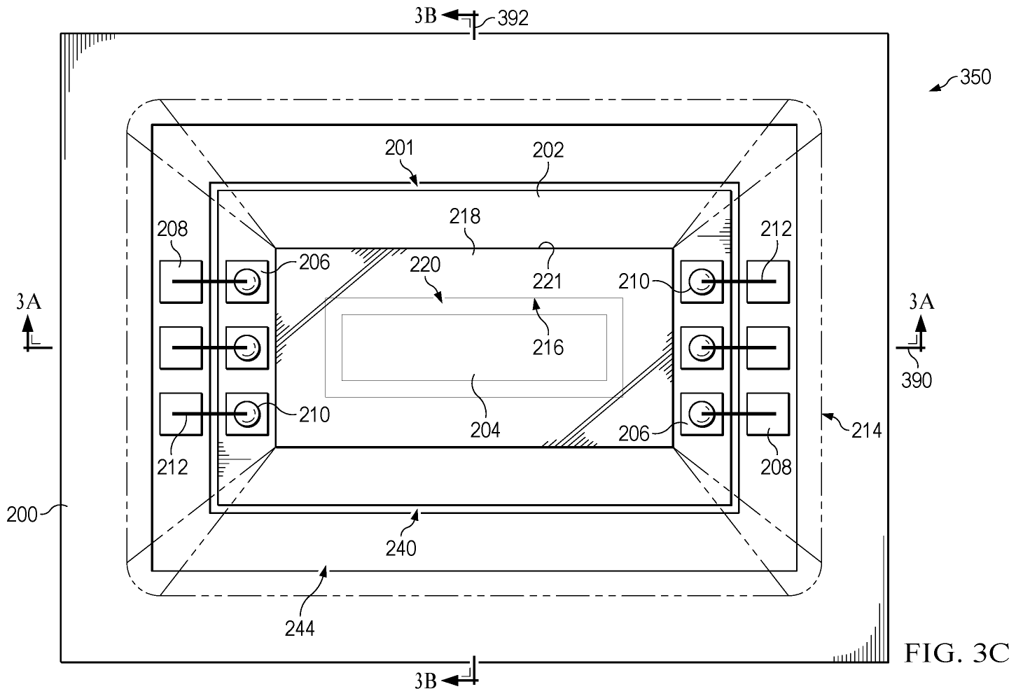

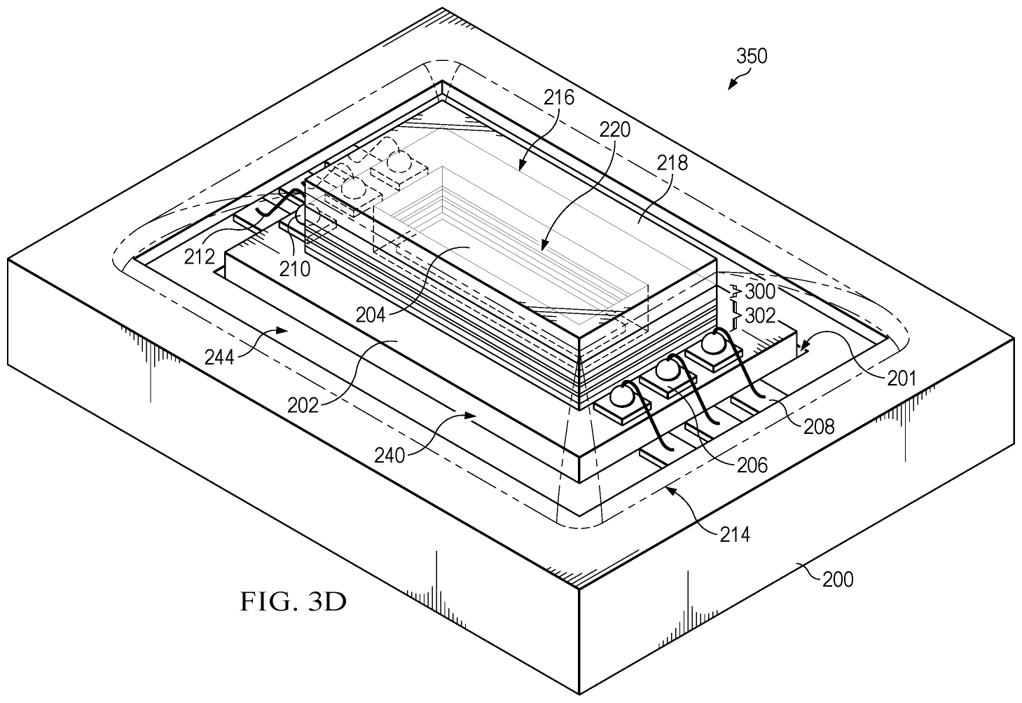

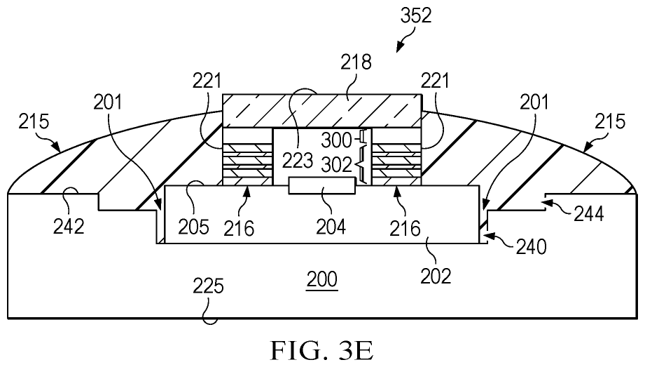

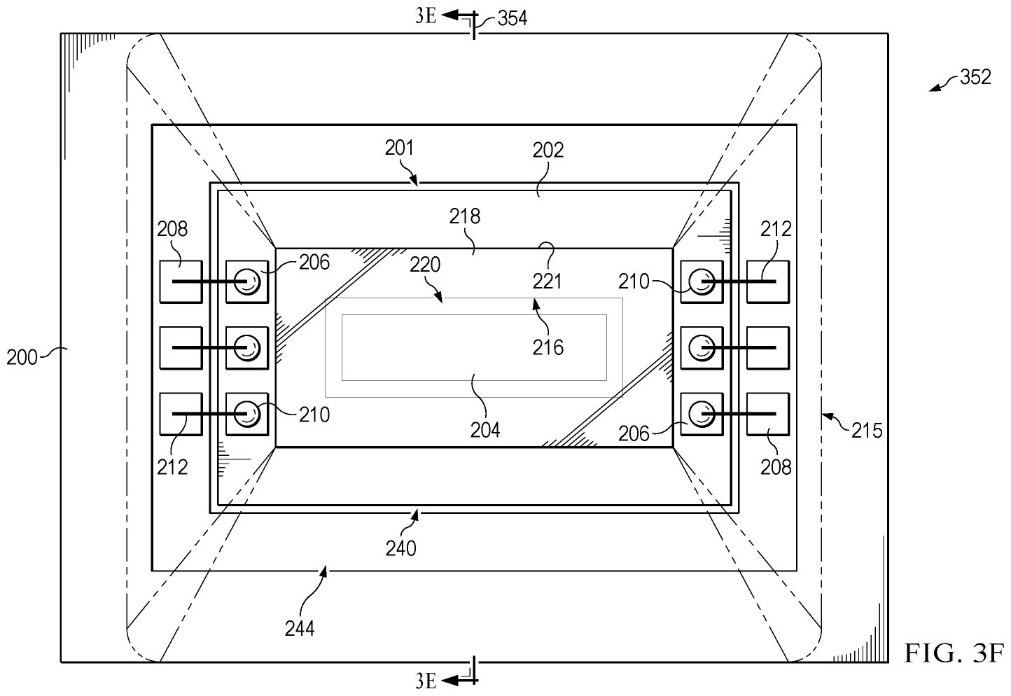

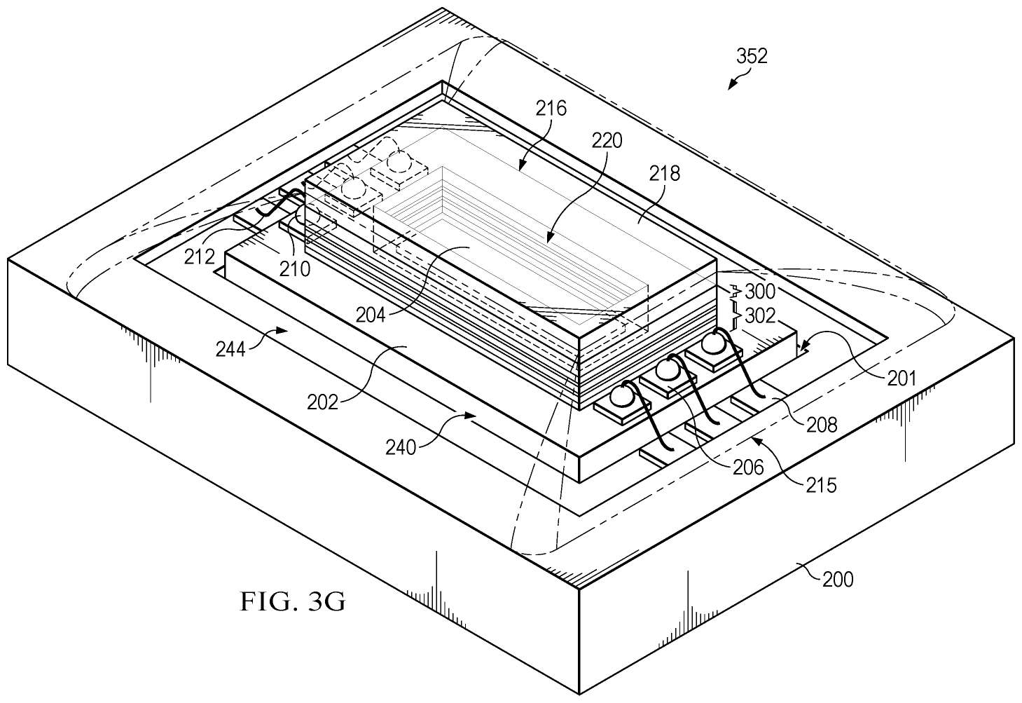

FIGS. 3A and 3B are different cross-sectional views of an example MEMS device 350 (which is an example of MEMS device 104), in accordance with various examples. FIG. 3C is a top-down view of the MEMS device 350 of FIGS. 3A and 3B, in accordance with various examples. FIG. 3D is a perspective view of the MEMS device 350 of FIGS. 3A-3C, in accordance with various examples. The cross-section of FIG. 3A is taken along line 390 and the cross-section of FIG. 3B is taken along line 392, as shown in FIG. 3C. The MEMS device 350 of FIGS. 3A-3D is substantially similar to the MEMS device 250 of FIGS. 2A-2D, except that the structure 216 in the MEMS device 350 of FIGS. 3A-3D has a more specific composition. In particular, the structure 216 includes an interposer 300, such as a semiconductor (e.g., silicon, gallium nitride) interposer, that is positioned in between and contacting the cap 218 and a metal stack 302. The metal stack 302 may include multiple different metals, multiple metal alloys, multiple oxide layers, glass, semiconductors, and other materials that together facilitate the formation and preservation of a seal, for example a hermetic seal, protecting the cavity 220. Example materials in the metal stack 302 include copper, nickel, etc. Other materials not specifically listed are also contemplated and included in the scope of this disclosure. Different layers in the metal stack 302 may have different shapes and physical dimensions. In some examples, the MEMS device 350 may include a single metal stack, and in other examples, the MEMS device 350 may include multiple metal stacks. Any of a variety of configurations of the metal stack(s) and semiconductor interposer(s) are contemplated and included in the scope of this disclosure.

FIG. 3E is a cross-sectional view of an example MEMS device 352, which is an example of MEMS device 104 and is identical to the example MEMS device 350 of FIGS. 3A-3D, except that an epoxy 215 is extended to one or more edges of the perimeter of the substrate 200, as in FIG. 2E. FIG. 3F is a top-down view of the MEMS device 352 of FIG. 3E, in accordance with various examples. FIG. 3F shows where the cross-section of FIG. 3E is taken, along line 354. FIG. 3G is a perspective view of the MEMS device 352 of FIGS. 3E and 3F, in accordance with various examples.

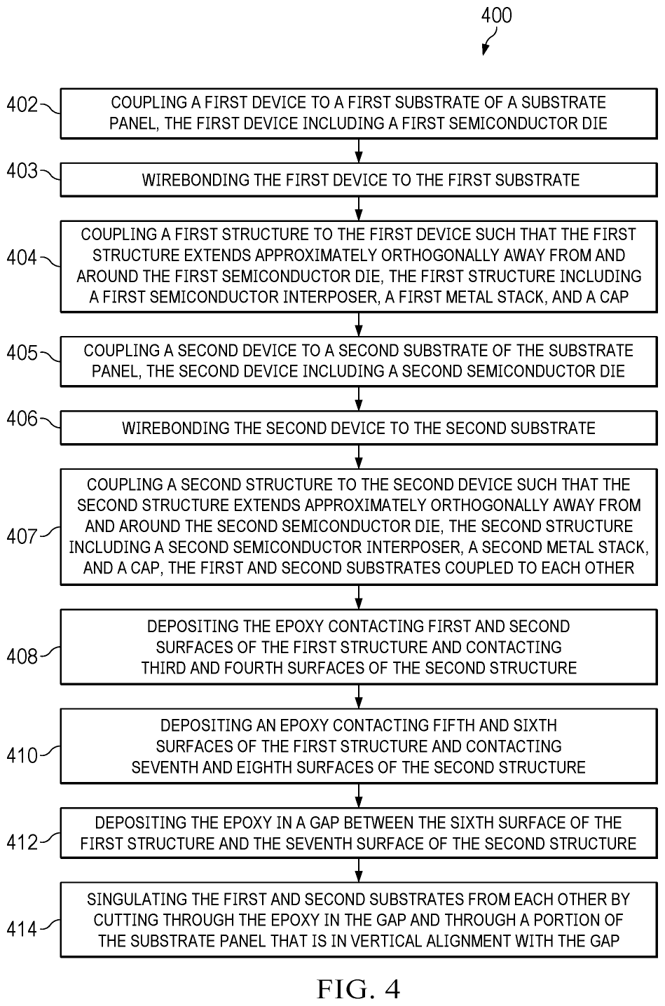

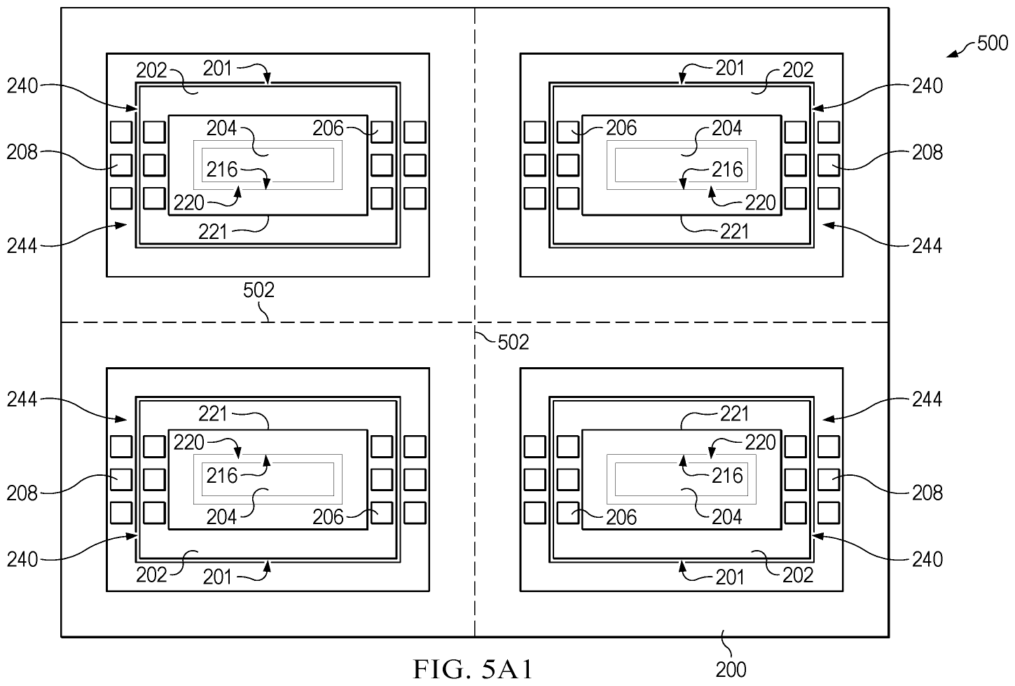

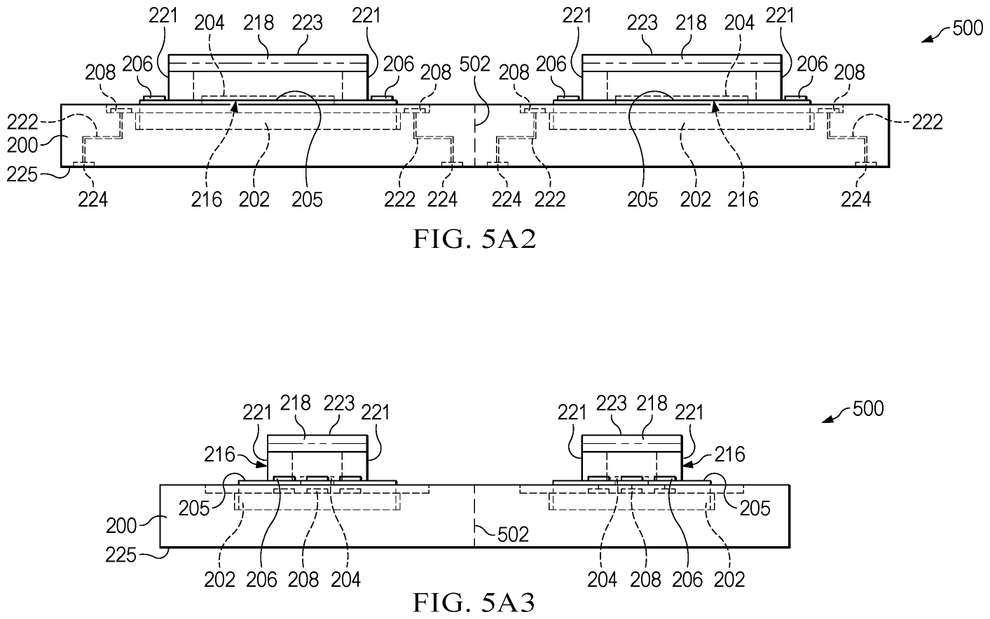

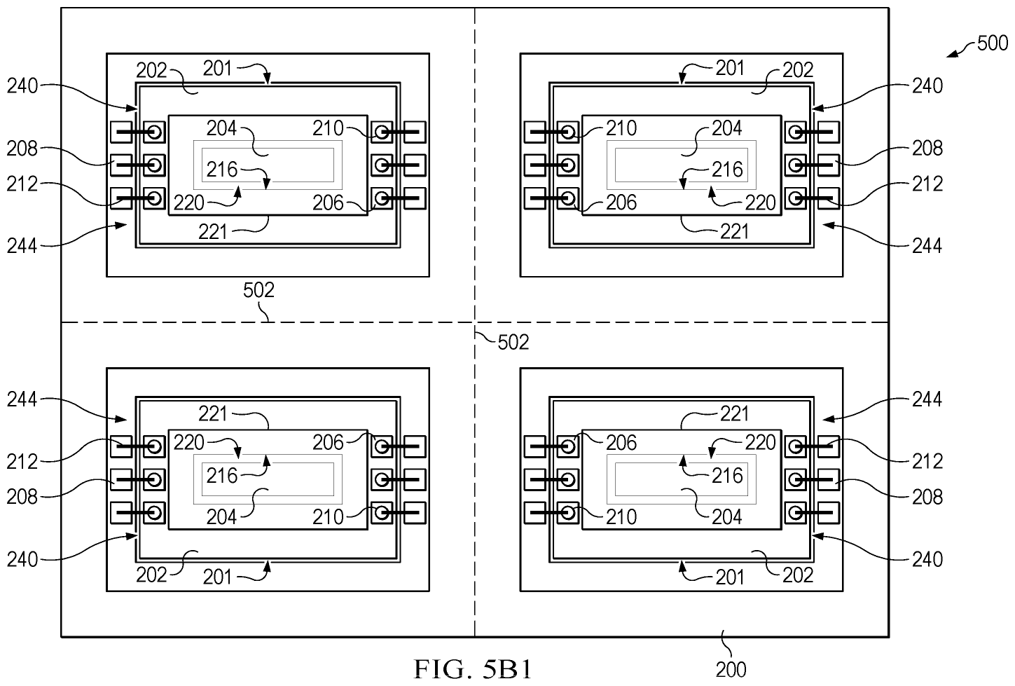

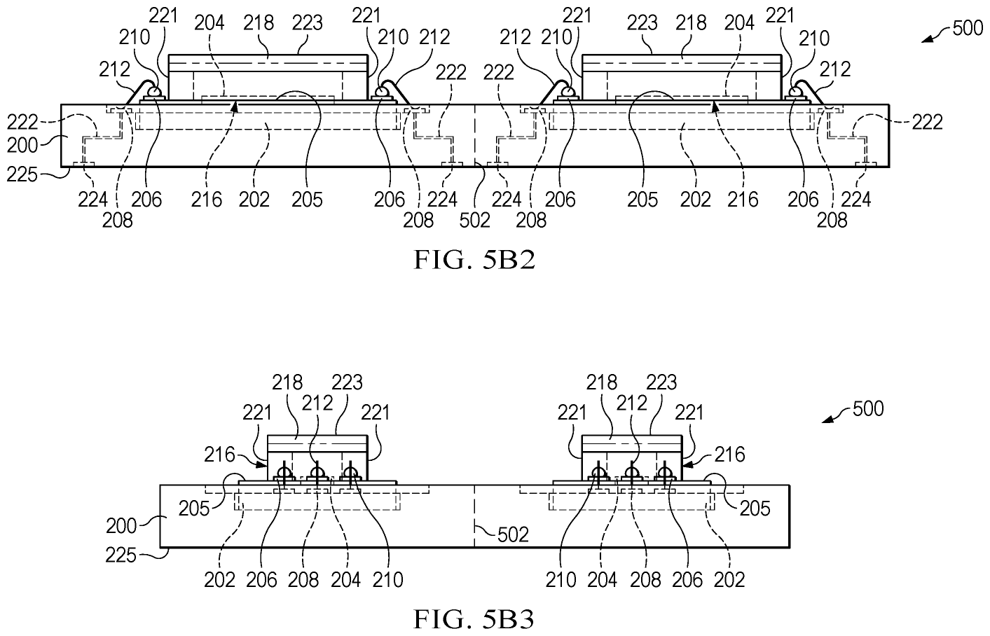

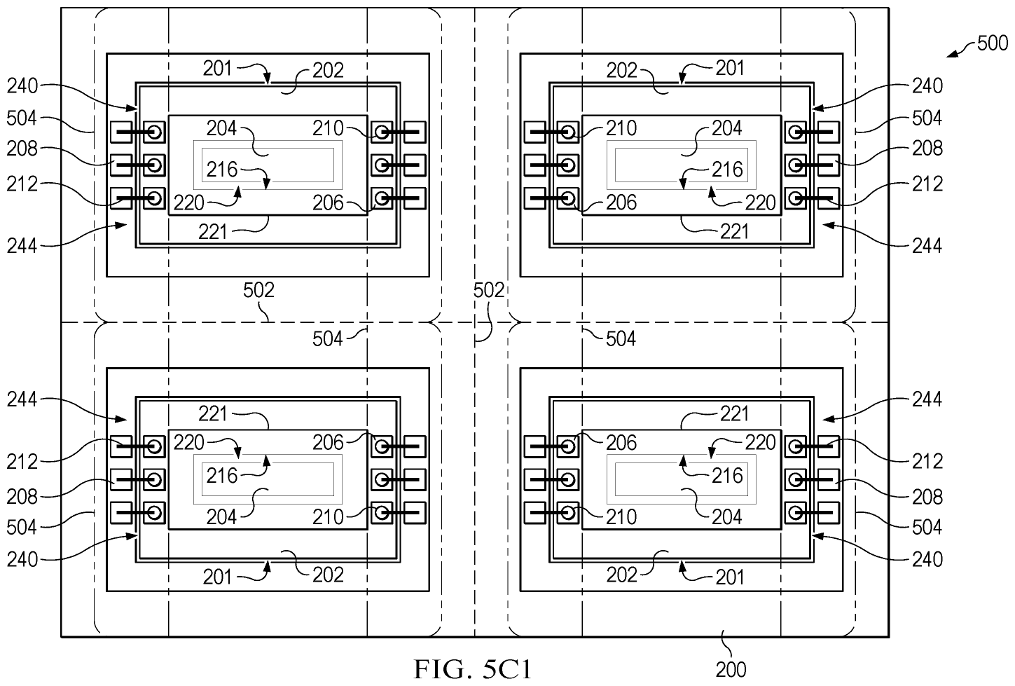

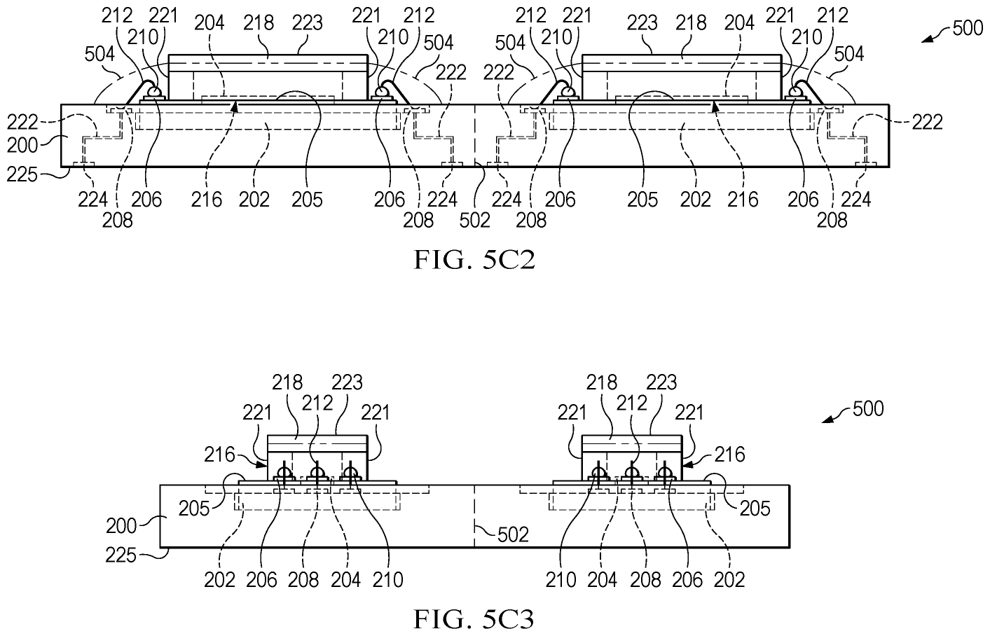

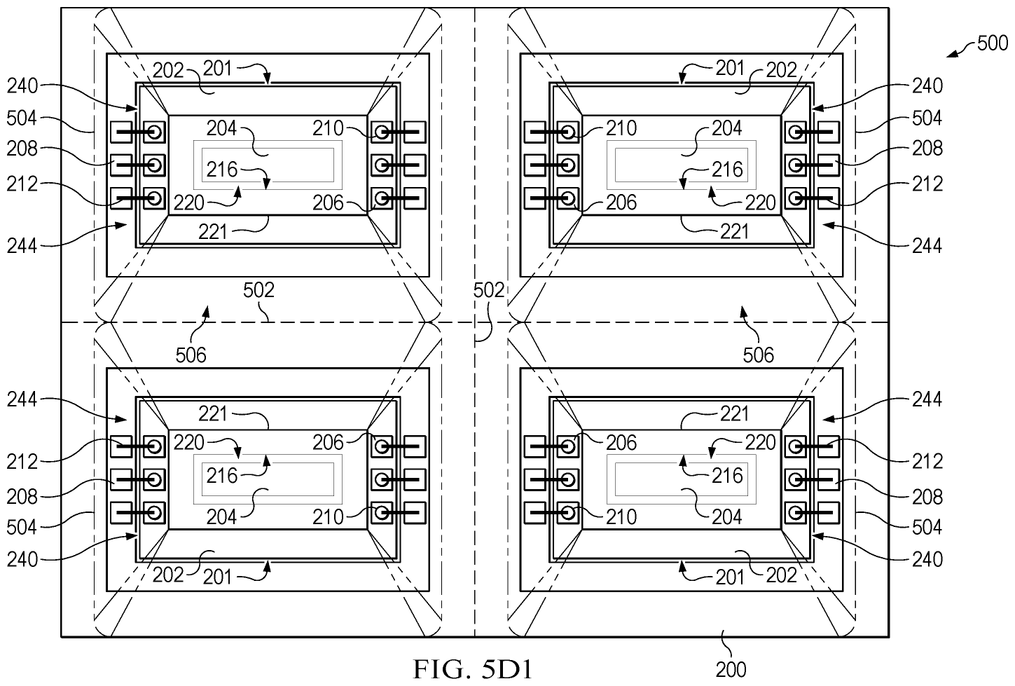

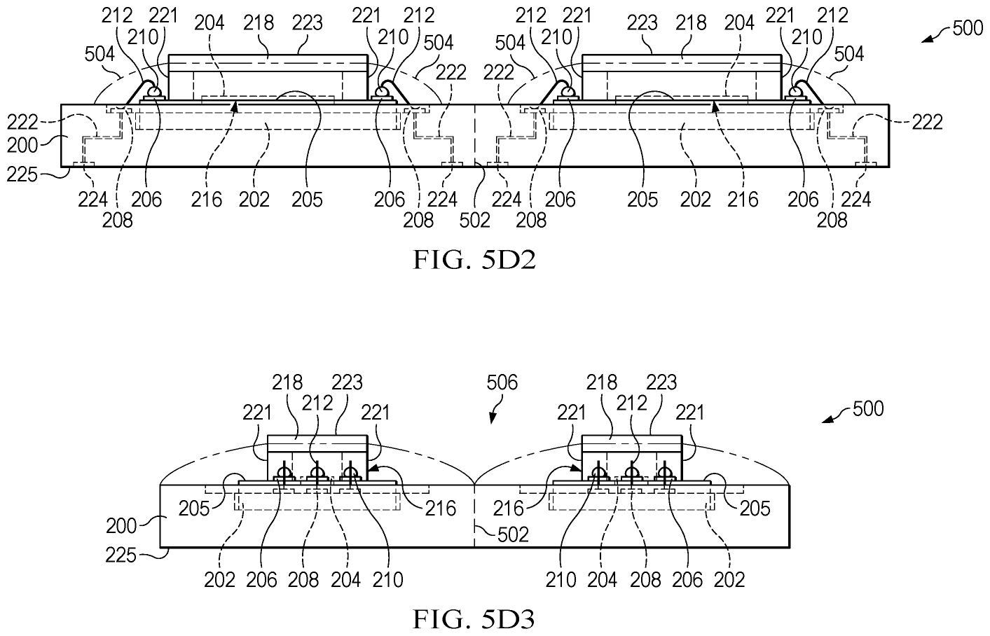

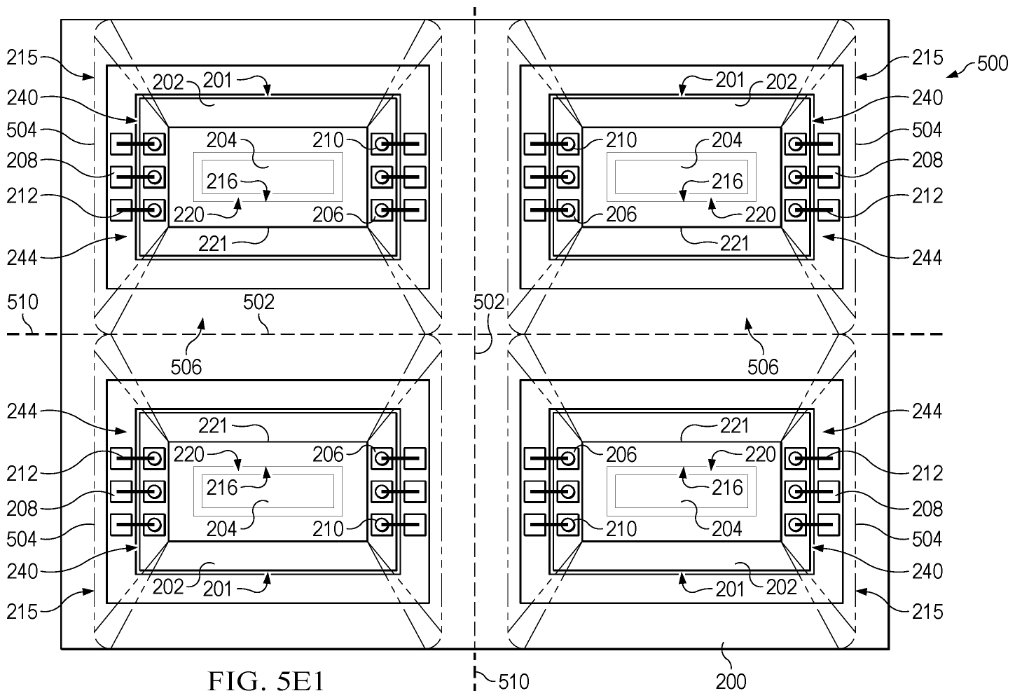

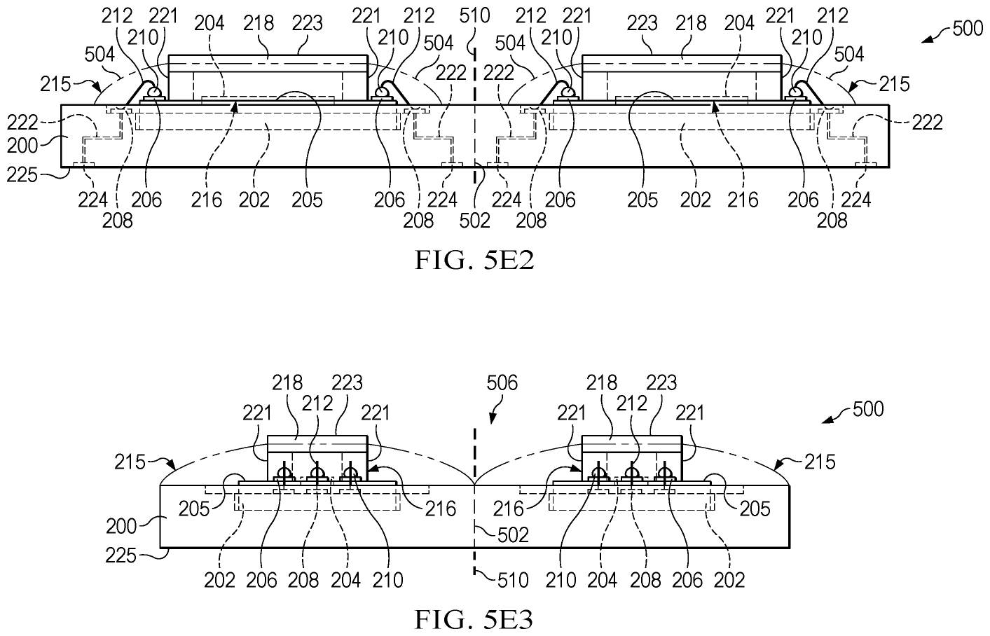

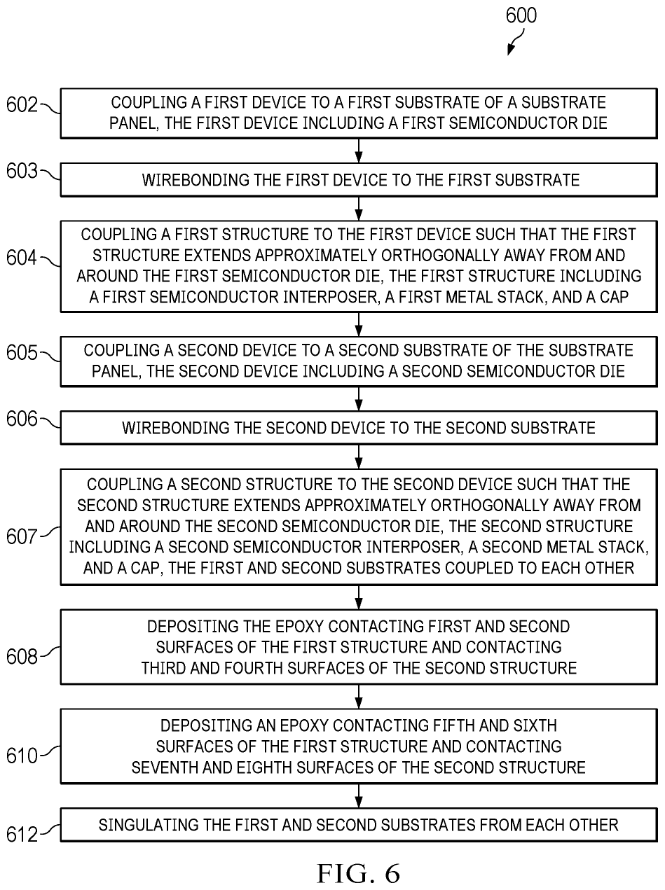

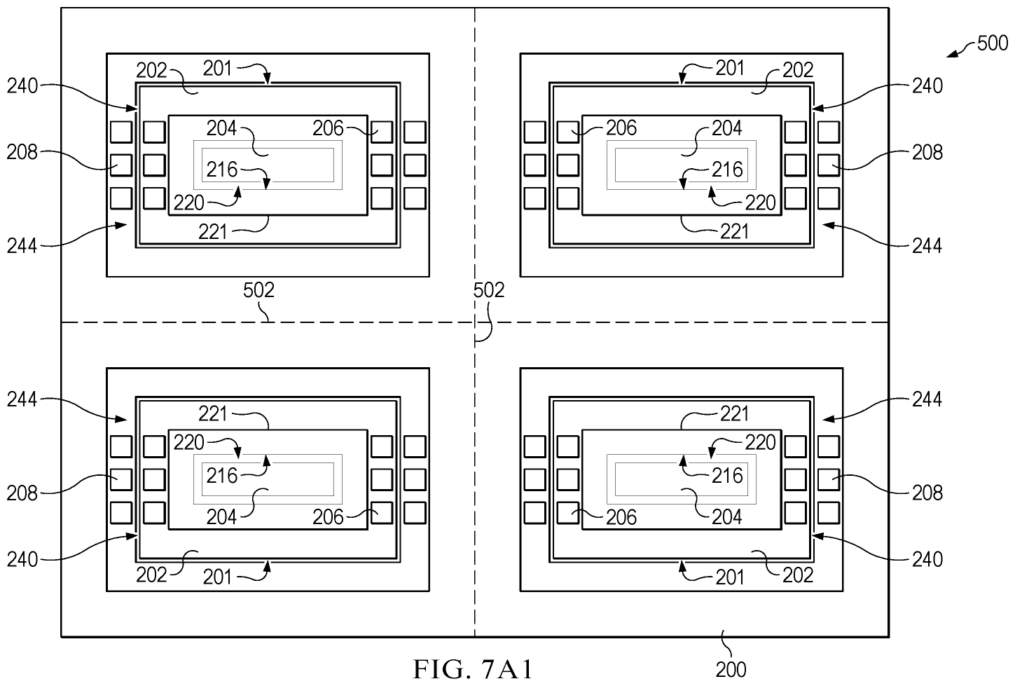

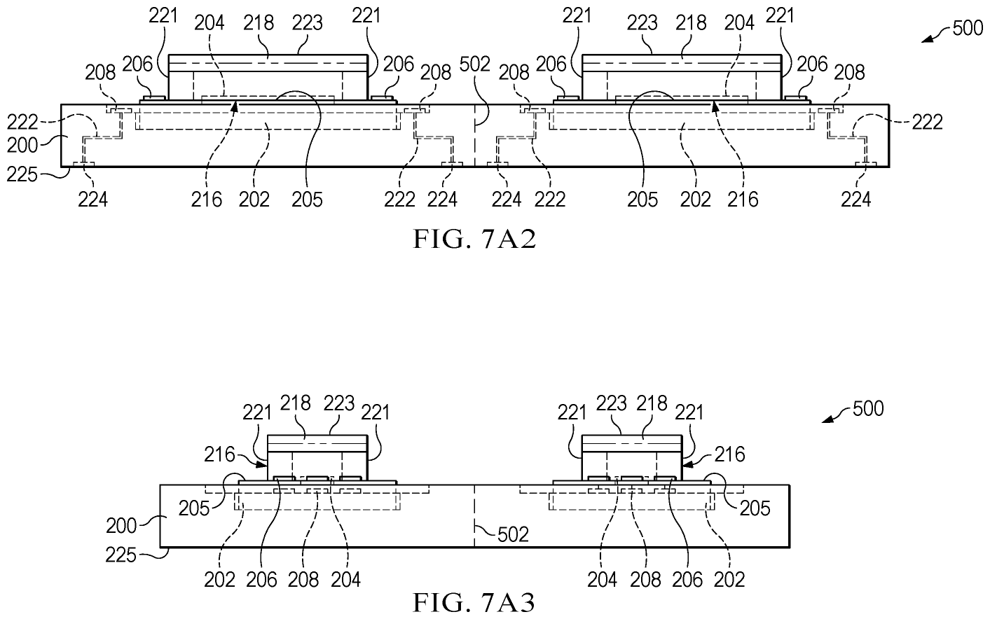

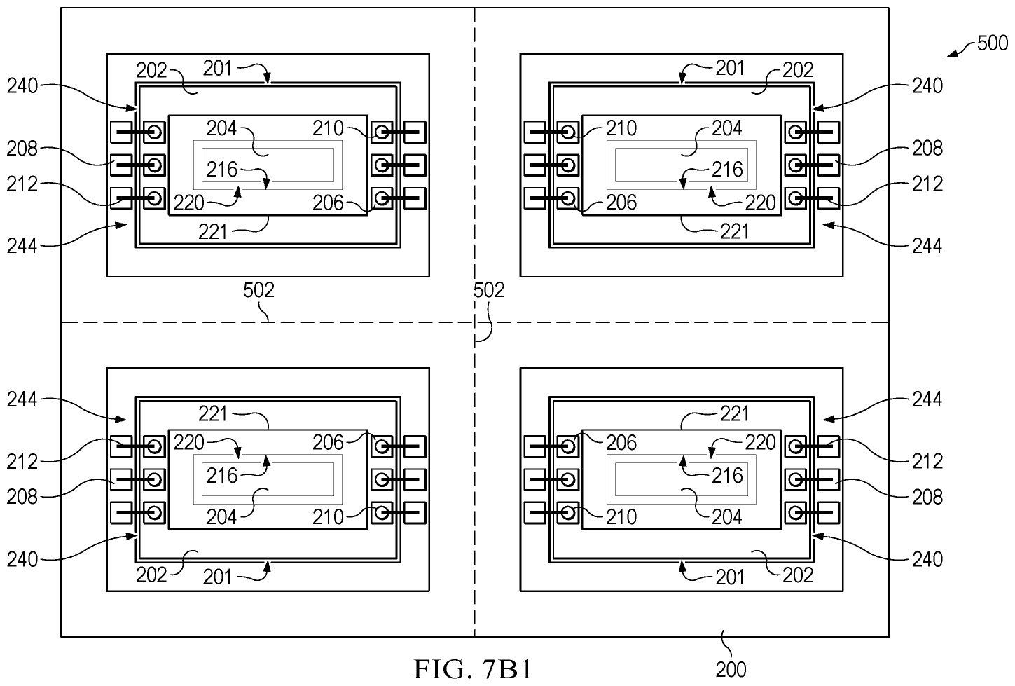

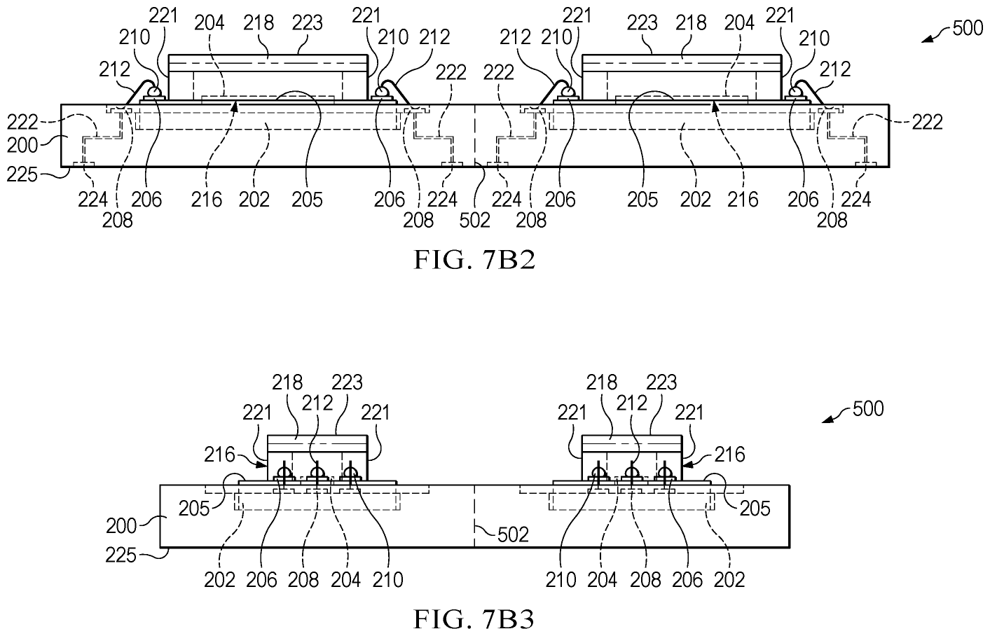

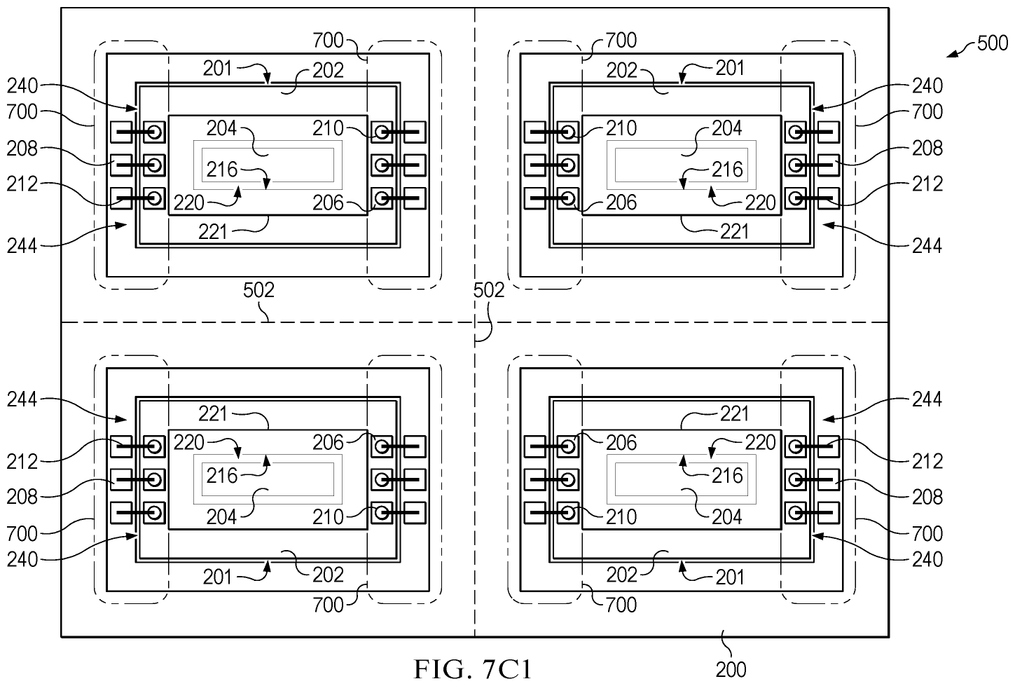

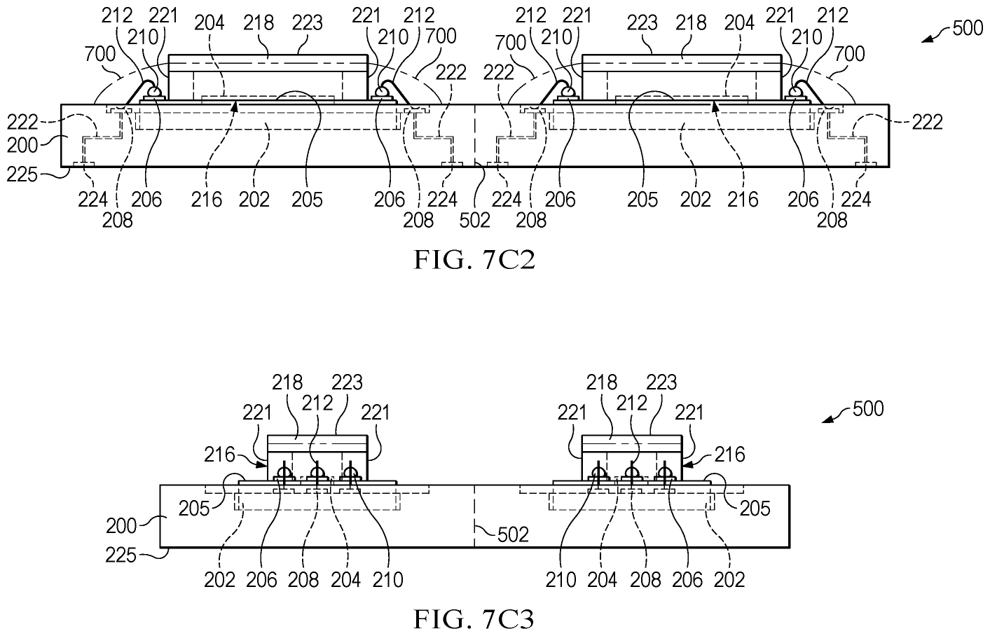

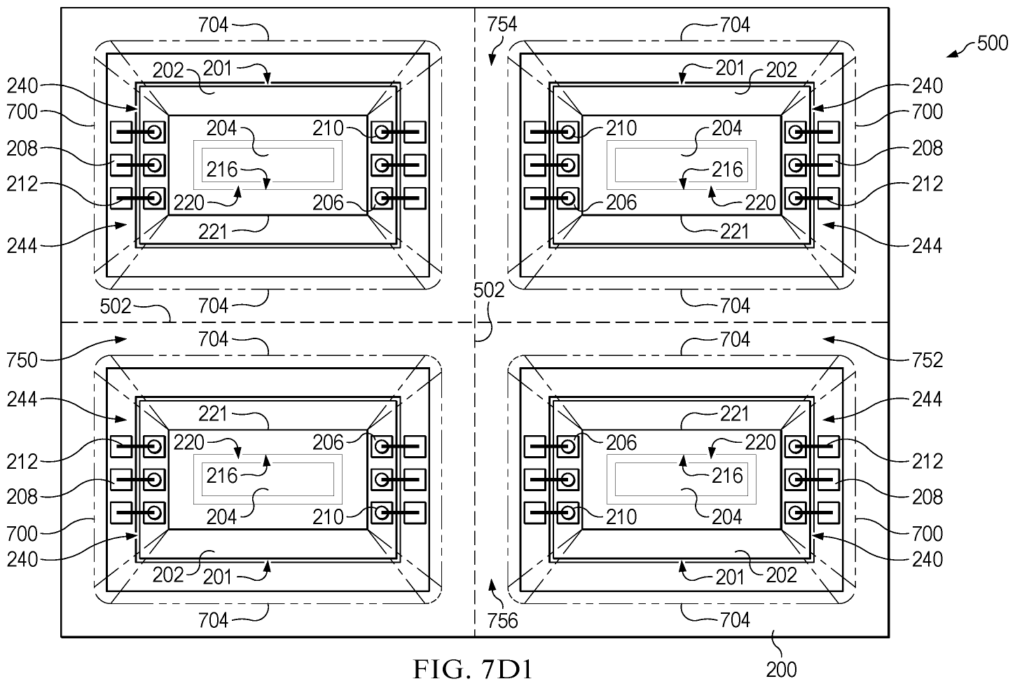

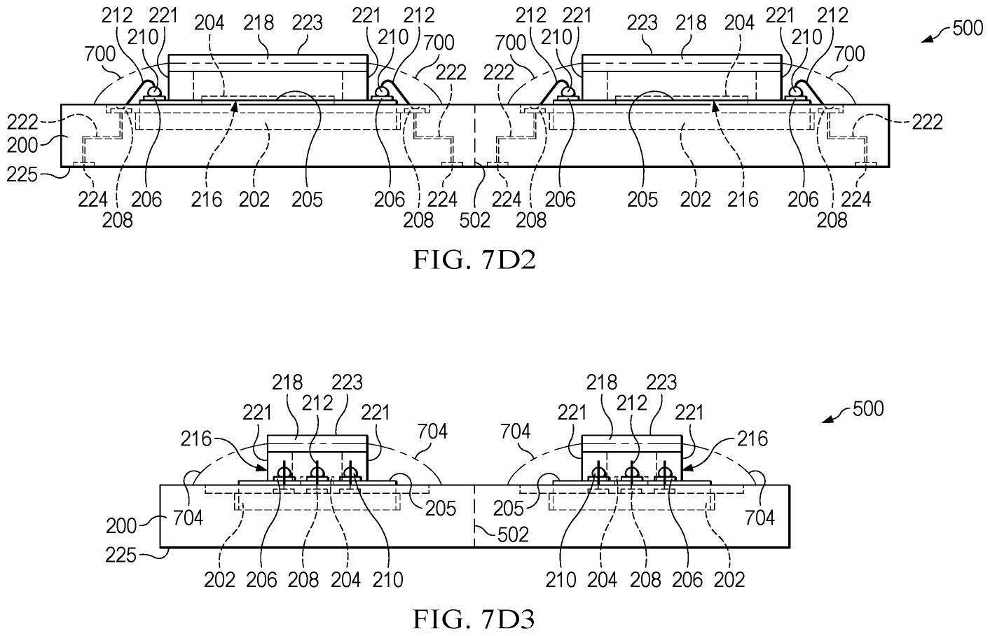

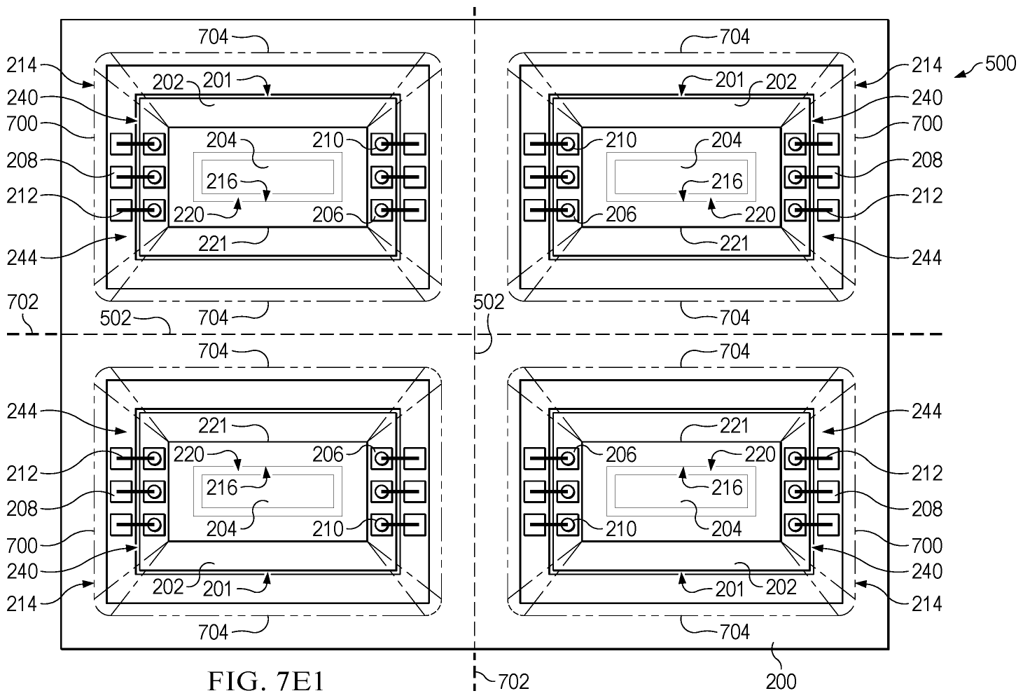

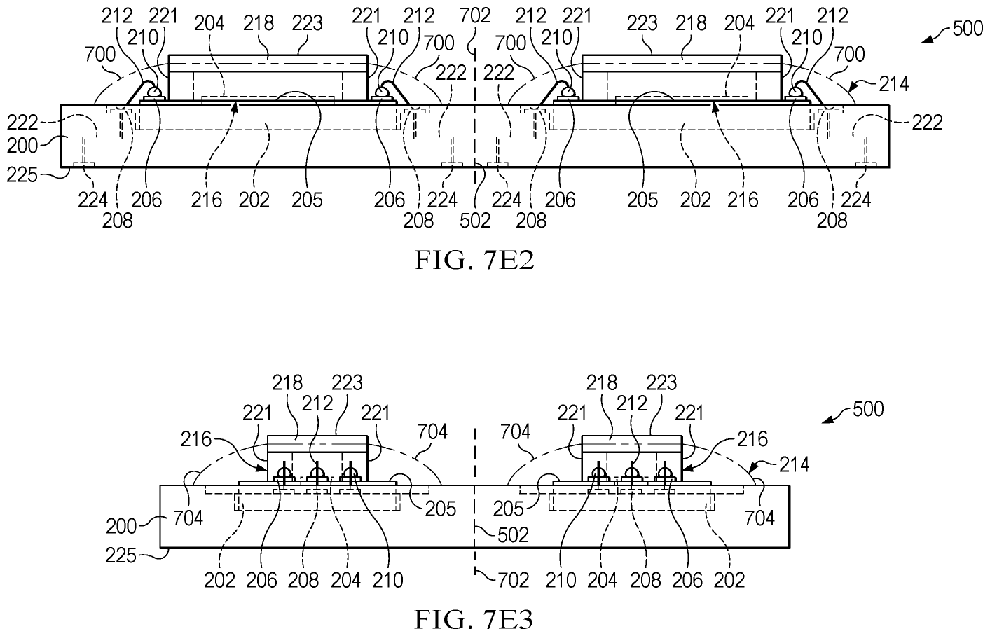

As described above, in some examples of the MEMS device 104 (e.g., MEMS devices 252 and 352), the epoxy 215 extends to one or more edges of a perimeter of the substrate 200 (e.g., as shown in FIGS. 2E-2G, and 3E-3G). In other examples of the MEMS device 104 (e.g., MEMS devices 250 and 350), the epoxy 214 does not extend to the edges of the perimeter of the substrate 200 (e.g., as shown in FIGS. 2A-2D and 3A-3D). Techniques for manufacturing each of these two types of MEMS devices are now described. Specifically, FIG. 4 is a flow diagram of a method 400 for manufacturing a MEMS device 104 (e.g., MEMS device 252 or 352) with epoxy 215 extending to the edges of the substrate 200 perimeter, and FIGS. 5A1-5E3 are a process flow for manufacturing the MEMS device 104 (e.g., MEMS device 252 or 352) with epoxy 215 extending to the edges of the substrate 200 perimeter. Thus, FIGS. 4 and 5A1-5E3 are now described in parallel. Further, FIG. 6 is a flow diagram of a method 600 for manufacturing a MEMS device 104 (e.g., MEMS device 250 or 350) with epoxy 214 that does not extend to the edges of the substrate 200 perimeter, and FIGS. 7A1-7E3 are a process flow for manufacturing the MEMS device 104 (e.g., MEMS device 250 or 350) with epoxy 214 that does not extend to the edges of the substrate 200 perimeter. Thus, FIGS. 6 and 7A1-7E3 are described in parallel, further below.

Referring now to FIGS. 4 and 5A1-5E3, the method 400 (the steps of which may be performed in any suitable order) includes coupling a first device to a first substrate of a substrate panel (402). The first device includes a first semiconductor die (402). The method 400 includes wirebonding the first device to the first substrate (403). The method 400 also includes coupling a first structure to the first device such that the first structure extends approximately orthogonally away from and around the first semiconductor die, where the first structure includes a first, optional semiconductor interposer, a first metal stack, and a cap (404).The method 400 also includes coupling a second device to a second substrate of the substrate panel (405). The second device includes a second semiconductor die (405). The method 400 includes wirebonding the second device to the second substrate (406). The method 400 also includes coupling a second structure to the second device such that the second structure extends approximately orthogonally away from and around the second semiconductor die, where the second structure includes a second, optional semiconductor interposer, a second metal stack, and a cap (407). The first and second substrates are coupled to each other (407). FIG. 5A1 is a top-down view of an example substrate panel 500 that includes four regions, which will later be singulated to become four substrates 200, joined along perforations 502. FIG. 5A2 is a profile view of the substrate panel 500, and FIG. 5A3 is another profile view of the substrate panel 500. Although the example substrate panel 500 includes four substrates 200, other example substrate panels 500 may include more or fewer substrates 200. In examples, the substrate panel 500 is scored with perforations 502 between the substrates 200 to facilitate subsequent singulation of the substrate panel 500 into individual substrates 200. The substrates 200 include bond leads 208. Each substrate 200 includes a device, which includes at least a semiconductor die 202 and a structure 216. FIG. 5B1 is a top-down view of the substrate panel 500 of FIG. 5A1, except that multiple devices are wirebonded to the substrates 200 of the substrate panel 500. FIGS. 5B2 and 5B3 are profile views of the structure of FIG. 5B1, in accordance with various examples. These devices are similar to the MEMS devices 104 described herein, except that the substrates 200 and epoxies 215 are not yet parts of the devices. (After the devices are coupled to the substrates 200 and epoxies 215 have been deposited, it may be said that multiple MEMS devices 104 have been formed, but for the sake of consistency in nomenclature, the devices are referred to as “MEMS devices” instead of “MEMS devices 104” until the substrates 200 and epoxies 215 are added, at which point the devices may be considered “MEMS devices 104.”) Such coupling may include coupling semiconductor dies of the devices to the substrates 200 (e.g., using die attach layers), wirebonding bond pads of the devices to the bond leads 208 of the substrates 200, and so on.

The method 400 includes depositing an epoxy (e.g., such as by dispensing the epoxy using a syringe- or cartridge-based system and a dispensing tip or nozzle) contacting first and second surfaces of the first structure and contacting third and fourth surfaces of the second structure (408). The method 400 includes depositing the epoxy contacting fifth and sixth surfaces of the first structure and contacting seventh and eighth surfaces of the second structure (410). The method 400 includes depositing the epoxy in a gap between the sixth surface of the first structure and the seventh surface of the second structure (412). FIG. 5C1 is a top-down view of the structure of FIG. 5B1, except that epoxy (e.g., mold compound) is deposited contacting first and second surfaces of the structure 216 shown in the top-left of FIG. 5C1 and contacting third and fourth surfaces of the structure 216 shown in the bottom-left of FIG. 5C1. Similarly, epoxy is deposited contacting first and second surfaces of the structure 216 shown in the top-right of FIG. 5C1 and contacting third and fourth surfaces of the structure 216 shown in the bottom-right of FIG. 5C1. FIGS. 5C2 and 5C3 are profile views of the structure of FIG. 5C1, in accordance with various examples. FIG. 5D1 is a top-down view of the structure of FIG. 5C1, except that epoxy (e.g., mold compound) is deposited contacting fifth and sixth surfaces of the structure 216 on the top-left of FIG. 5D1 and contacting seventh and eighth surfaces of the structure 216 on the bottom-left. Similarly, epoxy is deposited contacting fifth and sixth surfaces of the structure 216 on the top-right and contacting seventh and eighth surfaces of the structure 216 on the bottom-right. Epoxy is also deposited in the gap between the sixth surface of the structure 216 on the top-left and the seventh surface of the structure 216 on the bottom-left, and likewise between the sixth surface of the structure 216 on the top-right and the seventh surface of the structure 216 on the bottom-right, as numerals 506 indicate. FIGS. 5D2 and 5D3 are profile views of the structure of FIG. 5D1, in accordance with various examples.

Deposition of epoxy in the areas indicated by numerals 506 and subsequent singulation along the perforations 502 results in a MEMS device in which the epoxy extends to the edge of the perimeter of the substrate 200. For example, as FIG. 5D1 shows, epoxy is deposited on the top-left substrate 200 of the substrate panel 500 and on the bottom-left substrate 200 of the substrate panel 500 without a break or interruption in the epoxy (as FIG. 5D3 shows). Thus, later singulation along the perforation 502 that is between the top-left and bottom-left substrates 200 will result in a MEMS device in which the epoxy extends to the edge of the top-left substrate 200 that bordered the bottom-left substrate 200 prior to singulation, and, likewise, in a MEMS device in which the epoxy extends to the edge of the bottom-left substrate 200 that bordered the top-left substrate 200 prior to singulation. The epoxy may also extend to any other edges of a substrate 200 where the epoxy was similarly applied as between the top-left and bottom-left substrate 200 of the substrate panel 500. (Although the substrate panel 500 may have any number of substrates 200 in the horizontal plane, the terms “top-left substrate,” “bottom-left substrate,” etc. used with reference to FIG. 5D1 refer to the four substrates 200 expressly shown in FIG. 5D1.) The epoxy deposition technique shown in FIGS. 5D1 and 5D3 may be advantageous and useful in any of a variety of contexts, such as when the available space between consecutively adjacent semiconductor dies is minimal, or when faster manufacturing speed is especially desirable. The epoxy deposition technique shown in FIGS. 5D1 and 5D3 may be applied to selectively extend the epoxy to one or more edges of a substrate 200. In some instances, it may be disadvantageous, or of modest benefit, to extend the epoxy to the substrate edges in this manner. For example, in FIG. 5D1, the epoxy does not extend to the perforation 502 between the top-left substrate 200 and the top-right substrate 200, resulting in the cross-sectional view provided in FIG. 5D2. In this approach, epoxy is applied on the surface 242, just outside the perimeter of the shelf 244. Leaving a perforation 502 free of epoxy is advantageous because the substrate panel 500 may be singulated along the perforation 502 by applying pressure to break the substrate panel 500 rather than by using a saw to cut the substrate panel 500.

The method 400 includes singulating the first and second substrates from each other by cutting through the epoxy in the gap and through a portion of the substrate panel that is in vertical alignment with the gap (414). In some examples, the method 400 may include cutting through the epoxy in the gap and scribing and breaking the substrate panel in the area that is in vertical alignment with the gap. FIG. 5E1 is a top-down view of the structure of FIG. 5D1, except that the substrate panel 500 is being singulated as numeral 510 depicts, in accordance with various examples. FIGS. 5E2 and 5E3 are profile views of the structure of FIG. 5E1, in accordance with various examples. As FIGS. 5E1-5E3 show, the epoxy 215 contacts all four sides of the structure 216, thereby sealing and protecting the various components of the structure 216 from damage (e.g., oxidation) that would otherwise occur by exposure to the environment. In addition to contacting all four sides of the structure 216, the four corners of the structure 216 are likewise covered by the epoxy 215, thus forming a barrier that circumscribes the entirety of the structure 216. The structures that result from performance of the method 400 and the process flow in FIGS. 5A1-5E3 are shown in FIGS. 2E, 2F, and 2G.

Referring now to FIGS. 6 and 7A1-7E3, a method 600 (the steps of which may be performed in any suitable order) for manufacturing MEMS devices 104 (e.g., MEMS devices 250 and 350) includes coupling a first device to a first substrate of a substrate panel (602). The first device includes a first semiconductor die (602). The method 600 includes wirebonding the first device to the first substrate (603). The method 600 also includes coupling a first structure to the first device such that the first structure extends approximately orthogonally away from and around the first semiconductor die, where the first structure includes a first, optional semiconductor interposer, a first metal stack, and a cap (604). The method 600 includes coupling a second device to a second substrate of the substrate panel (605). The second device includes a second semiconductor die (605). The method 600 includes wirebonding the second device to the second substrate (606). The method 600 also includes coupling a second structure to the second device such that the second structure extends approximately orthogonally away from and around the second semiconductor die, where the second structure includes a second, optional semiconductor interposer, a second metal stack, and a cap (607). The first and second substrates are coupled to each other (607). FIG. 7A1 is a top-down view of an example substrate panel 500 having multiple substrates 200 separated from each other by perforations 502. Devices are coupled to the substrates 200, and these devices include at least semiconductor dies 202 and structures 216. FIGS. 7A2 and 7A3 are profile views of the structure of FIG. 7A1, in accordance with various examples. FIG. 7B1 is a top-down view of the structure of FIG. 7A1, except that the bond pads of the MEMS devices are coupled to the bond pads of the substrates 200 by way of wirebonding. FIGS. 7B2 and 7B3 are profile views of the structure of FIG. 7B1, in accordance with various examples.

The method 600 includes depositing an epoxy contacting first and second surfaces of the first structure and contacting third and fourth surfaces of the second structure (608). The method 600 also includes depositing the epoxy contacting fifth and sixth surfaces of the first structure and contacting seventh and eighth surfaces of the second structure (610). FIG. 7C1 is a top-down view of the structure of FIG. 7B1, except that epoxy 700 (e.g., mold compound) has been deposited contacting first and second surfaces of the structures 216 on the top-left and top-right and contacting third and fourth surfaces of the structures 216 on the bottom-left and bottom-right. FIGS. 7C2 and 7C3 are profile views of the structure of FIG. 7C1, in accordance with various examples. FIG. 7D1 is a top-down view of the structure of FIG. 7C1, except that epoxy 704 (e.g., mold compound) has been deposited contacting the fifth and sixth surfaces of the structure 216 on the top-left and top-right and on seventh and eighth surfaces of the structure 216 on the bottom-left and bottom-right. FIGS. 7D2 and 7D3 are profile views of the structure of FIG. 7D1, in accordance with various examples. As opposed to the examples of FIGS. 5D1-5D3, in which epoxy was extended to at least some substrate 200 edges, in the examples of FIGS. 7D1-7D3, the epoxy is not extended to any of the substrate 200 edges, which may be advantageous because a saw is not needed to singulate the substrate panel 500 along the perforations 502. Specifically, numerals 750, 752, 754, and 756 indicate gaps, i.e., the absence of epoxy between each pair of the four semiconductor dies 202 shown in FIG. 7D1.

The method 600 includes singulating (e.g., cutting or scribing and breaking) the first and second substrates from each other (612). FIG. 7E1 is a top-down view of the structure of FIG. 7D1, except that the substrate panel 500 is being singulated into individual substrates 200, as numeral 702 indicates. The singulation produces individual MEMS devices 104 (e.g., MEMS devices 250 or 350). FIGS. 7E1 and 7E2 are profile views of the structure of FIG. 7E1, in accordance with various examples. FIGS. 2A-2D show cross-sectional, cross-sectional, top-down, and perspective views, respectively, of the completed MEMS devices 104 (e.g., MEMS devices 250 or 350) formed by the performance of method 600 and the process flow of FIGS. 7A1-7E3, in accordance with various examples. As FIGS. 7E1-7E3 show, the epoxy 214 contacts all four sides of the structure 216, thereby sealing and protecting the various components of the structure 216 from damage (e.g., oxidation) that would otherwise occur by exposure to the environment. In addition to contacting all four sides of the structure 216, the four corners of the structure 216 are likewise covered by the epoxy 214, thus forming a barrier that circumscribes the entirety of the structure 216.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is described herein as including certain components may instead be coupled to those components to form the described device. For example, a structure described as including one or more elements (such as one or more processors and/or controllers) may instead include one or more elements within a single physical device (e.g., a display device) and may be coupled to at least some of the elements to form the described structure either at a time of manufacture or after a time of manufacture, for example, by an end-user and/or a third-party.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A micro-electromechanical (MEMS) device, comprising:
a substrate;
a semiconductor die coupled to the substrate and including circuitry formed therein, the semiconductor die also including a bond pad coupled to the circuitry;
a structure extending away from the semiconductor die and having four sides, the structure comprising a corrodible material; and
an epoxy contacting outer surfaces of the four sides of the structure and over the corrodible material.

2. The MEMS device of claim 1, further comprising a first bond wire coupling the semiconductor die to a first side of the substrate and a second bond wire coupling the semiconductor die to a second side of the substrate, the second side of the substrate opposite the first side of the substrate, the epoxy over the first wire bond and the second wire bond.

3. The MEMS device of claim 1, wherein the MEMS device further comprises a cap coupled to the semiconductor die by way of the structure to form a sealed cavity between the cap, the structure, and the semiconductor die.

4. The MEMS device of claim 3, wherein the cap is a glass member, and wherein the epoxy does not contact a surface of the glass member that faces away from the semiconductor die.

5. The MEMS device of claim 1, wherein the structure comprises a metal stack coupled to a semiconductor interposer.

6. The MEMS device of claim 1, wherein the epoxy extends to an edge of the substrate.

7. The MEMS device of claim 1, wherein a gap separates the epoxy from an edge of the substrate.

8. A micro-electromechanical (MEMS) device, comprising:
a substrate including a bond lead;
a semiconductor die coupled to the substrate and including a bond pad coupled to the bond lead by way of a bond wire, the semiconductor die having a device side;
a four-sided structure comprising a metal stack, the four-sided structure coupled to the device side of the semiconductor die and to a glass member and forming a sealed cavity between the semiconductor die and the glass member; and
an epoxy contacting the metal stack on the four sides of the four-sided structure and over the bond wire.

9. The MEMS device of claim 8, wherein the metal stack comprises multiple different metals and multiple oxide layers, and wherein the multiple different metals comprise copper and nickel.

10. The MEMS device of claim 8, wherein the epoxy extends to an edge of the substrate.

11. The MEMS device of claim 8, wherein a gap separates the epoxy from an edge of the substrate.

12. The MEMS device of claim 8, wherein the metal stack comprises at least one of glass, oxide layers, and alloys.

13. The MEMS device of claim 8, wherein the epoxy has a coefficient of thermal expansion below 25.

14. The MEMS device of claim 8, wherein the four-sided structure comprises a semiconductor interposer coupled to the metal stack.

15. The MEMS device of claim 8, wherein the epoxy does not contact any part of a top surface of the glass member, the top surface of the glass member facing away from the semiconductor die.

16. A method of manufacturing a micro-electromechanical (MEMS) device, comprising:
attaching a first semiconductor die to a substrate panel;
attaching a first structure to the substrate panel around the first semiconductor die, the first structure comprising a first metal stack;
attaching a second semiconductor die to the substrate panel;
attaching a second structure to the substrate panel around the second semiconductor die, the second structure comprising a second metal stack;
depositing an epoxy contacting first and second surfaces of the first structure and contacting third and fourth surfaces of the second structure and in a gap between the second surface of the first structure and the third surface of the second structure; and
singulating the substrate panel comprising cutting through epoxy in the gap and through a portion of the substrate panel.

17. The method of claim 16, wherein the epoxy is composed of at least 80% silica.

18. The method of claim 16, wherein the epoxy has a coefficient of thermal expansion below 25.

19. The method of claim 16, wherein each of the first and second structures includes a semiconductor interposer.

20. The method of claim 16, further comprising attaching a glass member to the first semiconductor die by way of the first structure, and wherein a top surface of the glass member facing away from the first semiconductor die is not covered by the epoxy.
